(19) United States
(12) Patent Application Publication
(10) Pub. No.: US 2010/0104962 A1
(43) Pub. Date: Apr. 29, 2010

(54) PATTERNING METHOD, EXPOSURE SYSTEM, COMPUTER READABLE STORAGE MEDIUM, AND METHOD OF MANUFACTURING DEVICE

(75) Inventor: Shinichiro Koga, Utsunomiya-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/606,062

(22) Filed: Oct. 26, 2009

(30) Foreign Application Priority Data
Oct. 27, 2008 (JP) 2008-275924

(51) Int. Cl. G03F 7/20; G03B 27/42

(52) U.S. Cl. 430/30; 355/53

(57) ABSTRACT

A method includes measuring a line width of a pattern formed on a first substrate through forming a first edge and a second edge of the pattern on the first substrate, and determining, based on the measured line width, a correction value which corrects information for positioning the first substrate in the forming of the second edge so as to reduce variations in line width. The second edge is formed on a second substrate when positioning thereof in accordance with the information corrected by using the determined correction value.

### BACKGROUND OF THE INVENTION

1. Field of the Invention

The present invention relates to a patterning method, an exposure system, a computer readable storage medium, and a method of manufacturing a device.

2. Description of the Related Art

Recently, as semiconductor integrated circuits such as ICs and LSIs, and liquid crystal panels have become smaller in size and higher in integration degree, exposure apparatuses such as semiconductor exposure apparatuses have become higher in resolution and performance. In overlaying originals such as masks and reticles on substrates such as semiconductor substrates and glass substrates, in particular, a technique for overlaying originals on substrates on the order of nanometers is expected to be developed.

An overlay inspection and optimization method in an exposure method will be described next. FIG. 8 is a chart showing an outline of the overlay inspection and optimization method in the exposure method. An exposure apparatus aligns a substrate and exposes it to light. A developing apparatus develops the substrate. The exposed and developed substrate is fed to an overlay inspection apparatus, which in turn performs inspection for overlay error. The overlay inspection apparatus observes and measures a pattern for overlay inspection (to be referred to as an overlay inspection mark) formed on a wafer so as to measure any overlay error. If the overlay accuracy has not reached the standard value of a product, it is determined that the wafer or a lot as a process unit including the wafer is a defective product. A wafer or lot determined as a defective product is subjected to a rework process. A wafer or lot determined as a non-defective product proceeds to the next semiconductor device manufacturing step.

The measurement result obtained by the overlay inspection apparatus is used for not only the above inspection of a product but also for overlay optimization. An alignment offset (correction value) which corrects the overlay error measured by the overlay inspection apparatus is calculated and used as an offset when exposure is performed in a subsequent semiconductor manufacturing process. In this manner, feeding back overlay error caused in a previous manufacturing step will optimize an overlay.

On the other hand, with miniaturization of semiconductor integrated circuits and the like, techniques of forming finer patterns have been proposed. As one such technique, there is available double patterning (to be referred to as DP hereinafter), which is a technique of forming a desired pattern by performing exposure and edge formation twice each, by using different originals.

An outline of DP will be described with reference to FIG. 9. In DP, processing is sequentially performed from step A to step E in FIG. 9. First of all, in step A, a substrate 1001 having a process layer 1002 on which a pattern is to be formed and which is coated with a first resist 1003 is exposed to light through the first pattern and developed (this process will be referred to as the first exposure/development process). In step B, a first edge of the pattern is formed by the first etching using the first resist pattern formed by the first exposure/development process. In step C, the first resist is peeled off, a second resist 1003 is applied to the resultant structure, and the substrate 1001 is exposed to light through the second pattern and developed (this process will be referred to as the second exposure/development process). In step D, a second edge of the pattern is formed by using the second resist pattern formed by the second exposure/development process. Finally, in step E, the second resist is peeled off to form a desired pattern. Using this method can form a pattern smaller than the width of a pattern that can be transferred by the exposure apparatus.

A major characteristic of this method is that when overlay is properly performed in two exposure processes, a pattern line width L becomes uniform, as shown in FIG. 10A. In contrast, if overlay is not properly performed, pattern line widths L1 and L2 become nonuniform, as shown in FIG. 10B. For this reason, when using DP, overlay accuracy is important in maintaining the uniformity of pattern line widths.

As described above, in manufacturing semiconductor integrated circuits and liquid crystal panels, an original and a substrate are accurately overlaid by using the method including global alignment. In addition, overlay inspection and optimization are performed by using an overlay inspection apparatus. These make it possible to achieve a sufficiently high overlay accuracy.

In DP as a method of miniaturizing semiconductor integrated circuits and the like, using the method shown in FIG. 9 can improve the overlay accuracy to some extent. However, for the following reason, overlay accuracy optimization from a different viewpoint is required. As described above, unlike in the conventional method of forming a pattern by one exposure, in DP, overlay in forming the second pattern on the pattern formed first influences the line width of the pattern to be formed. The line width of the formed pattern influences the electrical characteristics of a semiconductor integrated circuit or the like. Stabilization of the line widths of patterns presents a significant challenge to the manufacture of semiconductor integrated circuits and the like. In general, the uniformity of the line widths of patterns is influenced by the amount of light for exposure of a pattern, a focus state, and a processed state after exposure of a pattern. In addition, as described above, in DP, overlay accuracy influences the uniformity of line widths of patterns. For this reason, in order to achieve high overlay accuracy and stabilize the uniformity of pattern line widths in DP, it may be necessary to perform overlay optimization in consideration of the relationship with factors, such as an exposure amount, which influence the uniformity of the line widths of patterns.

### SUMMARY OF THE INVENTION

The present invention reduces variations in the line widths of patterns in patterning that forms the edge of a pattern on a substrate in two steps.

According to an aspect of the present invention, there is provided a method of forming a pattern on a first substrate by forming a first edge of the pattern on the first substrate through formation of a first resist pattern by coating the first substrate with a first resist, exposing the first resist to light, and developing the first resist, forming a second edge of the pattern on the first substrate through formation of a second resist pattern by coating the first substrate with a second resist, exposing the second resist to light, and developing the second resist, the method comprising measuring a line width of the pattern formed on the first substrate, and determining, based on the measured line width, a correction value which corrects information for positioning the first substrate in the forming of the second edge so as to reduce variations in the line width, wherein a second edge is formed on a second substrate when positioning the second substrate in accordance with information corrected by using the determined correction value.

Further features of the present invention will become apparent from the following description of exemplary embodiments with reference to the attached drawings.

### BRIEF DESCRIPTION OF THE DRAWINGS

FIG. 1 is a chart showing an outline of a patterning method according to the present invention;

FIG. 2 is a schematic view of an exposure system according to the present invention;

FIG. 3 is a flowchart showing a patterning method according to the present invention;

FIG. 4 is a flowchart showing the details of part of the patterning method according to the present invention;

FIG. 5 is a schematic view of a substrate;

FIG. 6 is a schematic view of a measurement shot region;

FIG. 7 is a view for explaining a line width error;

FIG. 8 is a chart showing an outline of a conventional exposure method;

FIG. 9 is a schematic view of DP;

FIG. 10A is a view for explaining the influence of an overlay error in DP; and

FIG. 10B is a view for explaining the influence of an overlay error in DP.

### DESCRIPTION OF THE EMBODIMENTS

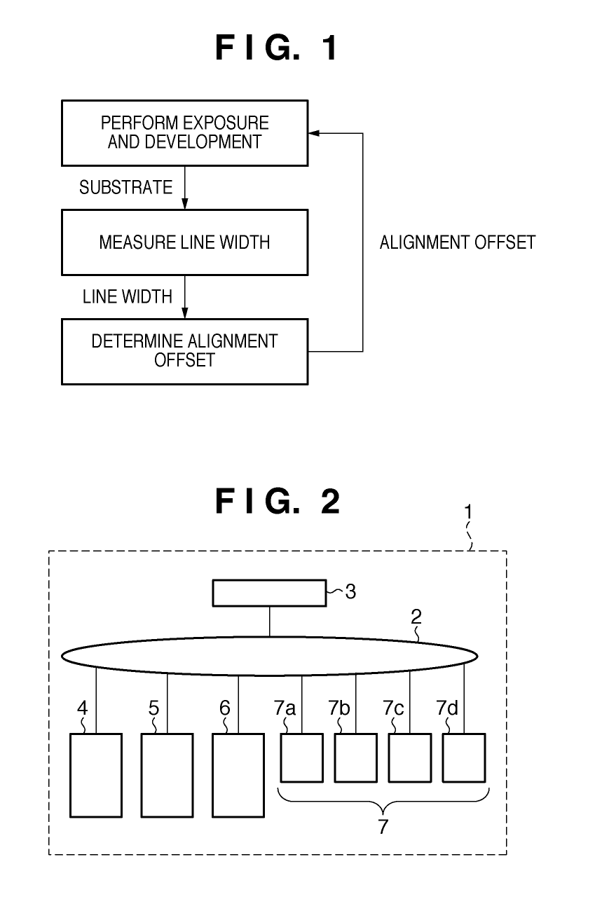

FIG. 1 shows an outline of patterning applied to the present invention. An exposure apparatus 4 (to be described later) exposes a substrate to light when overlaying an original on the substrate. A developing apparatus 7a then develops the substrate. Thereafter, the substrate is fed to a measurement device 5 (to be described later), which in turn measures the line width of a pattern formed on the substrate. After the substrate is etched based on the developed pattern, the substrate is fed to the measurement device 5, which in turn measures the line width of the etched pattern.

If the line width of the pattern has not reached the standard value of a product, the substrate or a lot including the substrate is determined as a defective product. A substrate or lot determined as a defective product is subjected to a rework process, whereas a substrate or lot determined as a non-defective product proceeds to the next manufacturing step. The measurement result obtained by the measurement device 5 is used for not only the above determination of a product but also overlay optimization. A determination unit 6 which determines a correction value (alignment offset) (to be described later) determines, based on the line width measured by the measurement device 5, an alignment offset as a correction value which corrects information for positioning a substrate in exposure for the formation of a second edge. The determined alignment offset is used as an offset (correction value) at the time of exposure in the same step in subsequent patterning. Positioning (overlay) of the substrate is optimized by feeding back the correction value based on the line width of the pattern generated in the previous step. This optimizes the positioning of the substrate based on the line width of the pattern.

An example of an exposure system 1 according to the present invention will be described with reference to FIG. 2. The exposure system 1 which manufactures a semiconductor device or the like includes an internal communication network 2 such as a local area network. A controller 3 is connected to the exposure apparatus 4, the measurement device 5, the determination unit 6, and other manufacturing apparatuses 7 via the internal communication network 2, and controls them. The other manufacturing apparatuses 7 can include a developing apparatus 7a, an etching apparatus 7b, an overlay inspection apparatus 7c, and a coating apparatus 7d. The respective apparatuses are connected to each other via the internal communication network 2.

The exposure apparatus 4 exposes the substrate to light while overlaying a pattern of an original on the substrate based on the alignment offset sent from the controller 3. The measurement device 5 is, for example, a known scanning electron microscope with a length measurement function (a length measurement SEM or CD-SEM). The scanning electron microscope with the length measurement function can acquire an electron beam image of a minute region of the substrate and measure the line width of the pattern formed on the substrate. The measurement device 5 measures the line width of a pattern of a resist (photoresist) on a substrate which is developed by the developing apparatus 7a after being exposed to light by the exposure apparatus 4, and the line width of the pattern having undergone a process such as etching based on the resist pattern. The determination unit 6 calculates and determines an alignment offset which corrects overlay at the time of exposure (an offset at the time of exposure) based on the line width of the pattern measured by the measurement device 5. The determination unit 6 can be implemented by a known computer.

This embodiment will exemplify the exposure system 1 as a system in which the exposure apparatus 4, the measurement device 5, the determination unit 6, and the like are connected to each other via the internal communication network 2. The exposure apparatus 4 in the exposure system 1 can be an exposure apparatus including a measurement unit and a determination unit in addition to an exposure unit.

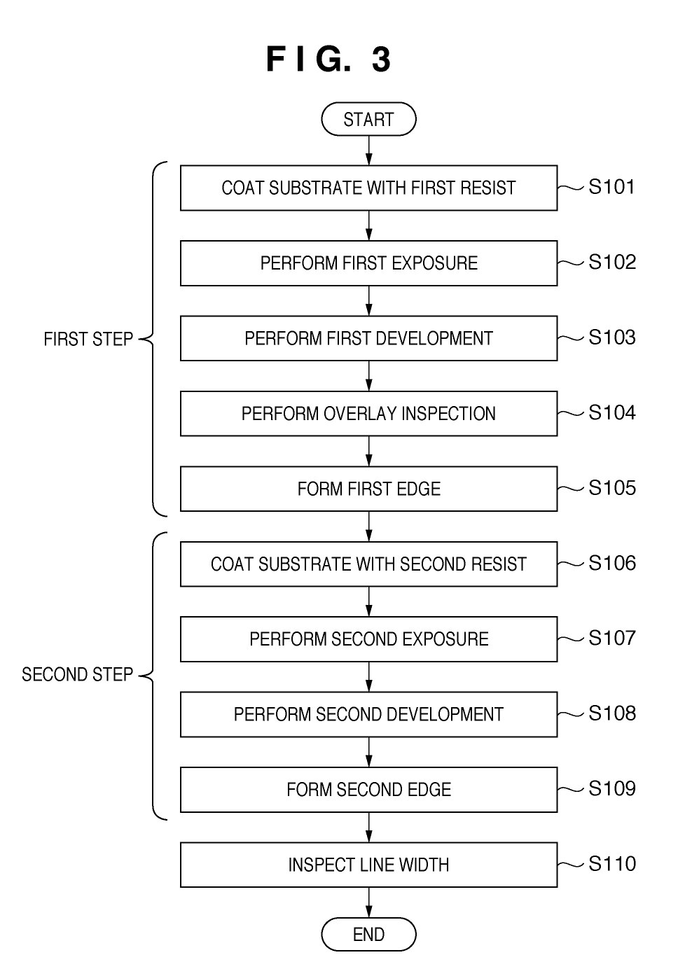

An example in which the present invention is applied to a method of forming a pattern on a substrate by double patterning (DP) will be described in detail next. FIG. 3 is a flowchart showing the patterning method.

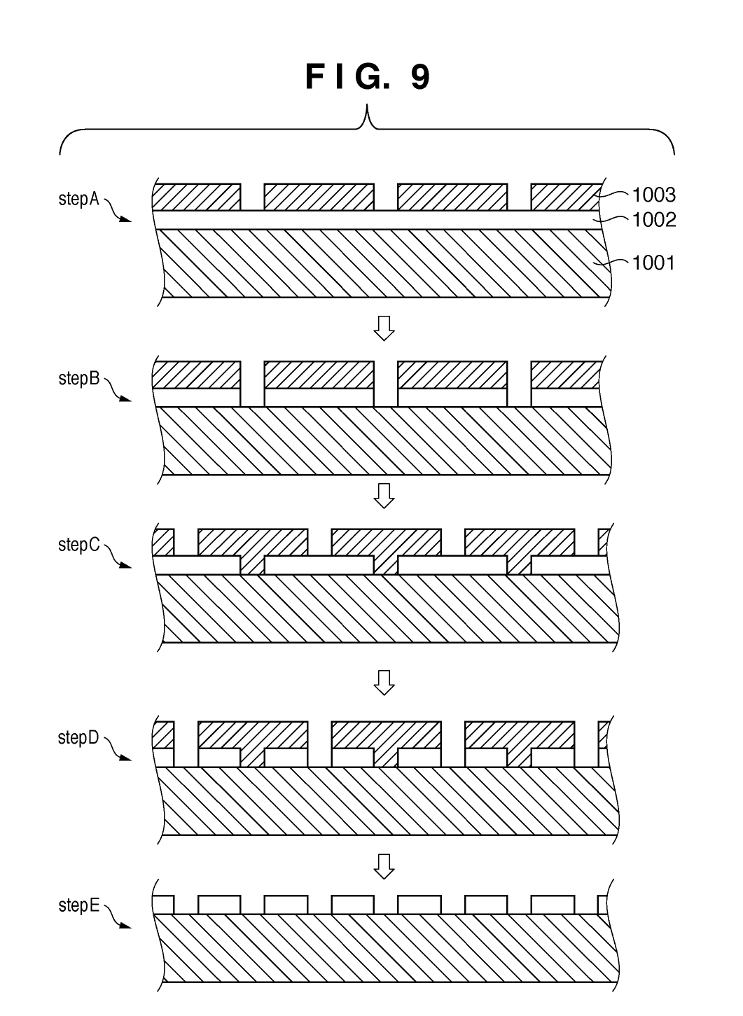

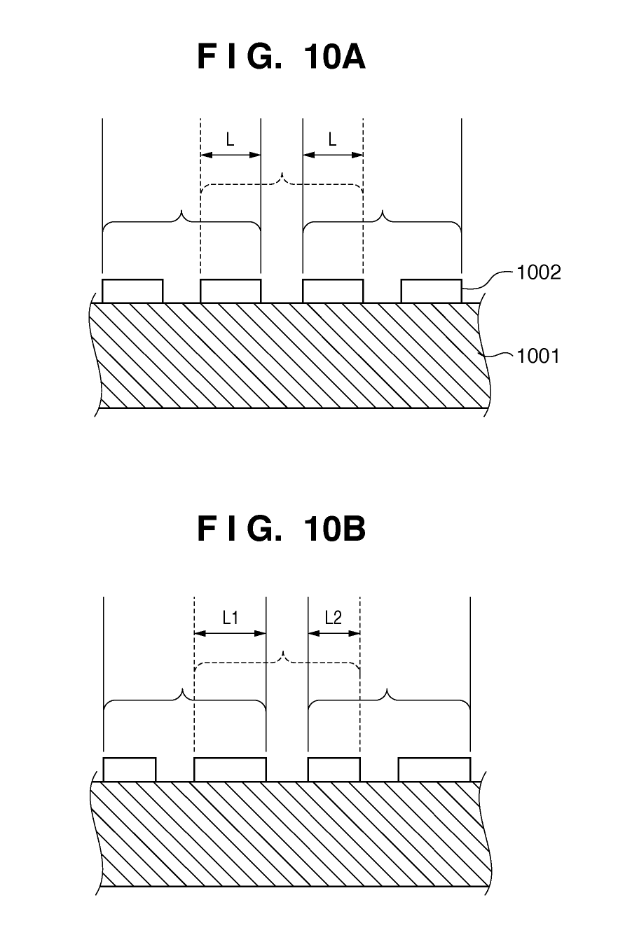

In step S101, the coating apparatus 7d coats the substrate with the first resist. Step S102 is the first exposure step. In this step, the exposure apparatus 4 exposes the first resist to light. Step S103 is the first developing step. In this step, the developing apparatus 7a forms the first resist pattern by developing the first resist exposed to light in the first exposure step. “Step A” in FIG. 9 indicates the state of the substrate at the end of the first developing step. Step S104 is the overlay inspection step (i.e., perform overlay inspection). In this step, the overlay inspection apparatus 7c inspects the overlay of the first resist pattern developed in the first developing step. In the overlay inspection step, the overlay inspection apparatus 7c observes and measures a mark for overlay which is formed on the wafer, as described earlier in reference to the prior art. The determination unit 6 calculates an alignment offset used in the first exposure step of subsequent patterning based on the mark measurement result.

Step S105 is the first etching step. The etching apparatus 7b forms a first edge of the pattern by etching a layer 1002, on which the pattern is to be formed, by using the first resist pattern developed in the first developing step, as indicated by “step B” in FIG. 9. The steps from step S101 to step S105 correspond to the first step in DP in which the first edge of a pattern is formed on a substrate through the formation of the first resist pattern.

In step S106, the coating apparatus 7d applies (i.e., coats substrate) the second resist on the substrate on which the first edge is formed. Step S107 is the second exposure step (i.e., perform second exposure). In this step, the exposure apparatus 4 exposes the second resist to light. In the second exposure step, the alignment offset which has already been determined by the determination unit 6 is transferred to the exposure apparatus 4, which in turn exposes the substrate to light while positioning it upon reflection of the transferred alignment offset. Step S108 is the second developing step (i.e., perform second development). In this step, the developing apparatus 7a forms the second resist pattern by developing the second resist. “Step C” in FIG. 9 indicates the state of the substrate at the end of the second developing step.

Step S109 is the second etching step. The etching apparatus 7b forms a second edge of the pattern by etching the layer 1002, on which the pattern is to be formed, by using the second resist pattern developed in the second developing step, as indicated by “step D” in FIG. 9. The second resist is then peeled off. The resultant substrate is the one indicated by “step E” in FIG. 9. An example of forming the second edge of the pattern in the second etching step has been described. However, the second etching step sometimes is not performed before the line width inspection step. For example, it is possible to leave the second resist pattern unchanged after the second developing step. The steps from step S106 to step S109 correspond to the second step in DP in which the second edge of the pattern is formed on the substrate through the formation of the second resist pattern.

Step S110 is the line width inspection step. In this step, the measurement device 5 measures the line width of the pattern formed on the substrate through the first and second steps, and the determination unit 6 inspects the measured line width. The determination unit 6 calculates and determines an alignment offset which corrects information for positioning the substrate in the second exposure step in subsequent DP. Using the alignment offset calculated and determined in the line width inspection step in this manner for DP for another substrate will optimize overlay and improve the uniformity of pattern line widths.

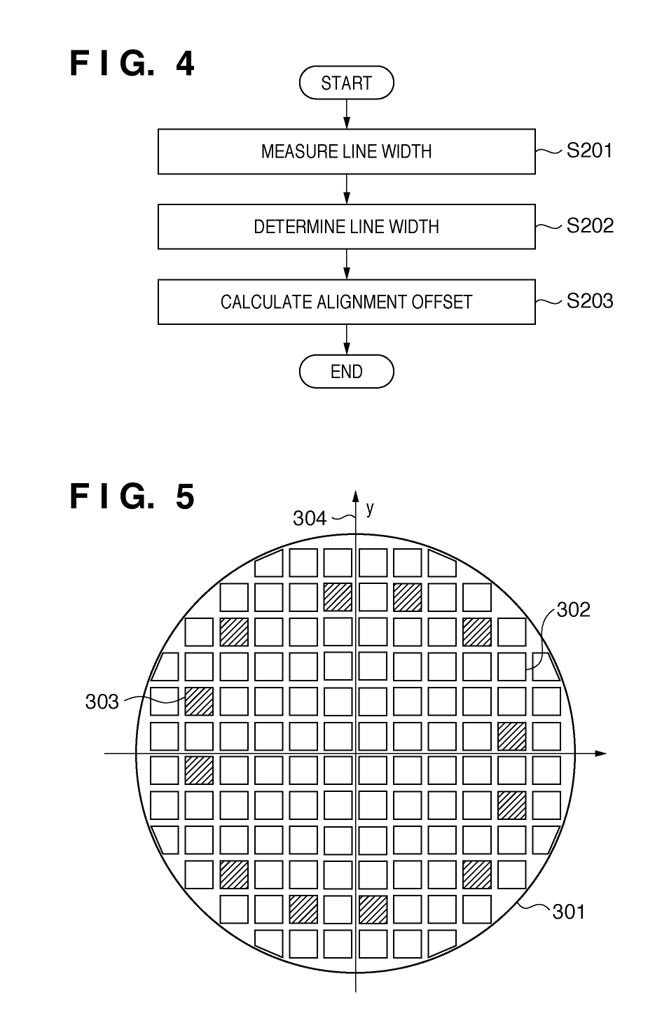

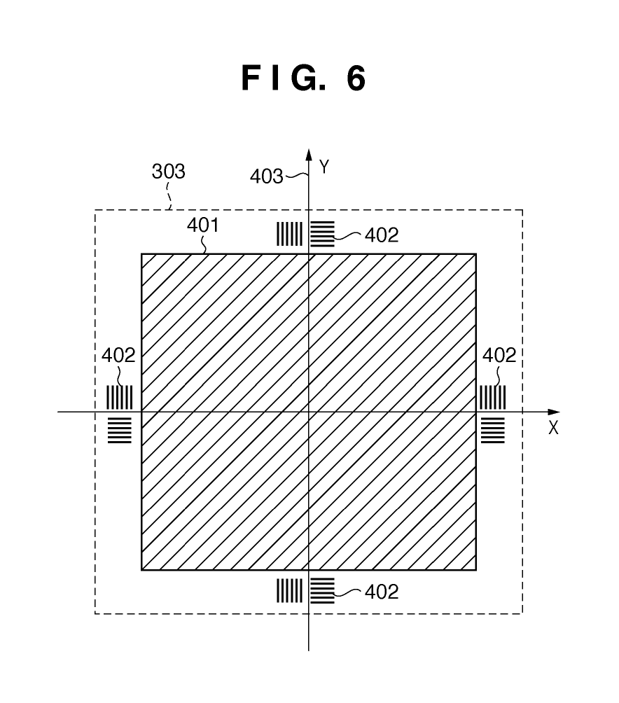

The details of the line width inspection step of step S110 will be described next with reference to FIG. 4. In step S201, the measurement device 5 measures the line width of the pattern formed on the substrate in the second etching step or the second developing step. The measurement device 5 measures the line width of the pattern at a plurality of positions in each of the selected shot regions of the plurality of shot regions on the substrate. The process continues to determine the line width at step S202 and calculate alignment offset at step S203. The details of line width measurement will be described with reference to FIGS. 5 and 6.

FIG. 5 is a schematic view of a substrate 301. A plurality of shot regions 302 as transfer regions are arrayed on the substrate 301. In general, the same pattern is exposed on the shot regions 302. A plurality of shot regions 303 (to be referred to as measurement shots) in which line widths are to be measured are selected, and only the patterns in the selected shot regions are measured.

FIG. 6 is a schematic view of the measurement shot 303. Reference numeral 401 denotes a transfer portion of a circuit pattern; and 402, a pattern (to be referred to as a measurement mark) for line width measurement. Note that coordinates (403 in FIG. 6) indicating a position in each measurement shot 303 will be referred to as shot coordinates. In addition, coordinates (304 in FIG. 5) indicating a position on the substrate 301 will be referred to as substrate coordinates. As shown in FIG. 6, in order to measure line widths at a plurality of positions in the measurement shot 303, a plurality of measurement marks 402 are arranged in the measurement shot 303. The line widths of the measurement marks 402 are measured. FIG. 6 shows an example of the arrangement of the four measurement marks 402 in each measurement shot 303. However, the number of measurement marks to be arranged is not limited to four. The following will exemplify a case in which line widths are measured by using the measurement marks 402 different from circuit patterns. However, it is possible to directly measure the line widths of circuit patterns without using any measurement marks. As described above, in the measuring step, the measurement shots 303 in which line widths are to be measured are selected from the shot regions 302 arrayed in the manner shown in FIG. 5 are selected, and the measurement device 5 measures the line widths of the measurement marks 402 in the measurement shots 303.

Step S202 is the line width determination step, in which the determination unit 6 calculates uniformity from a plurality of measured values obtained in step S201, and determines whether the uniformity falls within a predetermined standard value. When determining that the uniformity of the line widths has not reached the standard value, the determination unit 6 determines that the wafer or the lot including the wafer is a defective product. A wafer or lot determined as a defective product is subjected to a rework process (not shown). A wafer or lot determined as a non-defective product proceeds to the next manufacturing step.

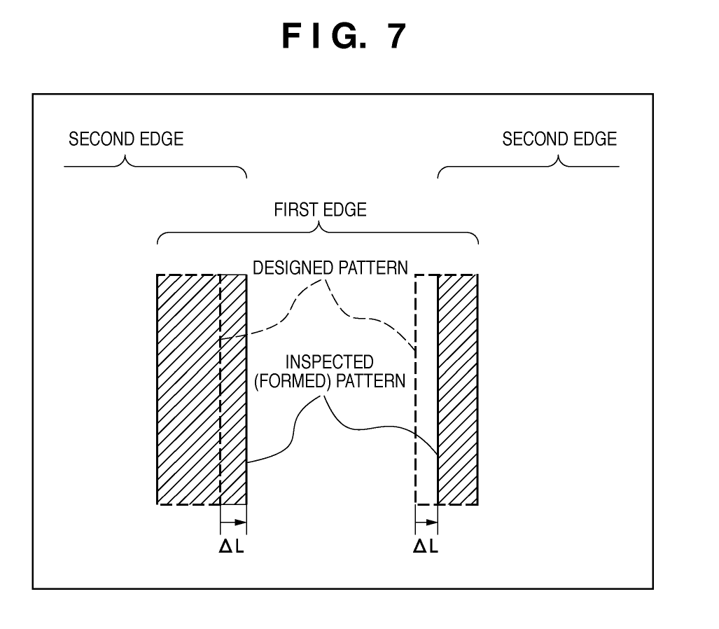

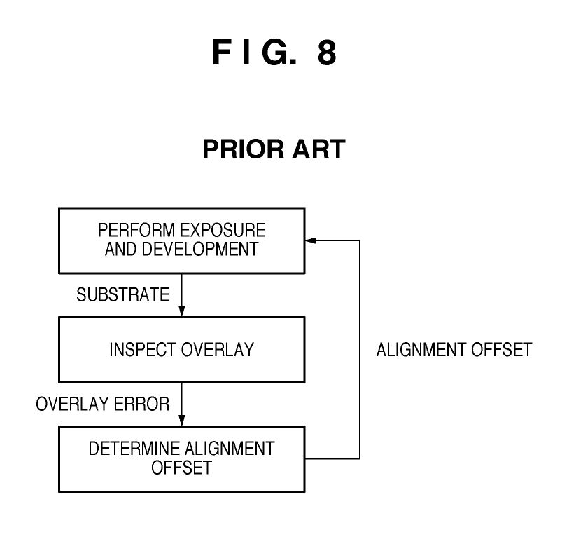

Step S203 is the determination step, in which the determination unit 6 calculates and determines an alignment offset so as to reduce variations in line width based on the plurality of measured values obtained in step S201. In the determination step, the determination unit 6 calculates a line width error from each measured value first. Assume that in this case, as shown in FIG. 7, the difference between the designed value (e.g., designed pattern) of a line width and the actual measured value (e.g., inspected (formed) pattern) of a line width is a line width error ΔL. Assume also that a line width error has, as a sign, the displacement direction (the arrow in FIG. 7) of the second edge formed in the second step relative to the first edge formed in the first step. According to this description, a line width error is calculated from the difference from the designed value. However, using the difference from the average value of the measured values of all line widths can also obtain the same effect of making line widths uniform. With this process, the determination unit 6 calculates a line width error at each measurement mark 402 in each measurement shot 303.

An example of a statistical process will be described in detail next, in which the determination unit 6 performs statistical calculation as in the method used in global alignment, and statistically processes the calculated line width error, thereby calculating an alignment offset as an overlay correction value for correcting a line width error. The statistical process is constituted by the following two processes. In the first statistic process, the determination unit 6 calculates line width error statistics in each measurement shot 303 based on a line width error in each measurement shot 303. In the second statistical process, the determination unit 6 calculates (estimates) the line width error statistics of all the shots from the line width error statistics in each measurement shot 303 calculated in the first statistical process, and determines the calculated statistics as an alignment offset.

The first statistical process will be described first. In the first statistical process, the determination unit 6 approximately assumes that a designed value (Xi, Yi) of a measurement position at shot coordinates and a measured line width error (Pₓ, P_{y}) approximately have the relationship represented by linear polynomials (1) and (2) given below. The determination unit 6 calculates, from these polynomials, a shift component (Sₓ[i], S_{y}[i]), a magnification component (Mₓ[i], M_{y}[i]), and a rotation component (Rₓ[i], R_{y}[i]) as the statistics of line width errors in a selected measurement shot i as the coefficients of these polynomials. More specifically, the determination unit 6 calculates the statistics of line width errors in the measurement shot i as the coefficients of polynomials (1) and (2) by a known least squares method using measured line width errors.

Pₓ(X,Y)=Sₓ[i]Mₓ[i]X+Rₓ[i]Y (1)

P_{y}(X,Y)=S_{y}[i]M_{y}[i]X R_{y}[i]Y (2)

The second statistical process will be described next. The determination unit 6 calculates the statistics of line width errors in all of a plurality of shot regions from the statistics of the line width errors in each measurement shot i obtained in the first statistical process.

The determination unit 6 assumes that a designed position (x, y) at the substrate coordinates of the center of an arbitrary shot region and a shift component (Sₓ, S_{y}), magnification component (Mₓ, M_{y}), and rotation component (Rₓ, R_{y}) in the shot region approximately have the relationship represented by arbitrary-order polynomials (3) to (8). The determination unit 6 obtains polynomials (3) to (8) for calculating the statistics of line width errors in all shot regions. More specifically, the determination unit 6 calculates polynomial coefficients aₛₓ to jₛₓ, a_{sy} to j_{sy}, aₘₓ to jₘₓ, a_{my} to j_{my}, aᵣₓ to jᵣₓ, and a_{ry} to j_{ry} based on the line width errors Sₓ[i], S_{y}[i], Mₓ[i], M_{y}[i], Rₓ[i], and R_{y}[i] in each measurement shot i. The determination unit 6 calculates coefficients of polynomials (3) to (8) by using a known least squares method.

Sₓ(xᵢ,yᵢ)=aₛₓ+bₛₓxᵢ+cₛₓyᵢ+dₛₓxᵢ²+eₛₓxᵢyᵢ+fₛₓyᵢ²+gₛₓxᵢ³+hₛₓxᵢ²yᵢ+iₛₓxᵢyᵢ²+jₛₓyᵢ³ . . . (3)

S_{y}(xᵢ,yᵢ)=a_{sy}+b_{sy}xᵢ+c_{sy}yᵢ+d_{sy}xᵢ²+e_{sy}xᵢyᵢ+f_{sy}yᵢ²+g_{sy}xᵢ³+h_{sy}xᵢ²yᵢ+i_{sy}xᵢyᵢ²+j_{sy}yᵢ³ . . . (4)

Mₓ(xᵢ,yᵢ)=aₘₓ+bₘₓxᵢ+cₘₓyᵢ+dₘₓxᵢ²+eₘₓxᵢyᵢ+fₘₓyᵢ²+gₘₓxᵢ³+hₘₓxᵢ²yᵢ+iₘₓxᵢyᵢ²+jₘₓyᵢ³ . . . (5)

M_{y}(xᵢ,yᵢ)=a_{my}+b_{my}xᵢ+c_{my}yᵢ+d_{my}xᵢ²+e_{my}xᵢyᵢ+f_{my}yᵢ²+g_{my}xᵢ³+h_{my}xᵢ²yᵢ+i_{my}xᵢyᵢ²+j_{my}yᵢ³ . . . (6)

Rₓ(xᵢ,yᵢ)=aᵣₓ+bᵣₓxᵢ+cᵣₓyᵢ+dᵣₓxᵢ²+eᵣₓxᵢyᵢ+fᵣₓyᵢ²+gᵣₓxᵢ³+hᵣₓxᵢ²yᵢ+iᵣₓxᵢyᵢ²+jᵣₓyᵢ³ . . . (7)

mₓ(xᵢ,yᵢ)=a_{ry}+b_{ry}xᵢ+c_{ry}yᵢ+d_{ry}xᵢ²+e_{ry}xᵢyᵢ+f_{ry}yᵢ²+g_{ry}xᵢ³+h_{ry}xᵢ²yᵢ+i_{ry}xᵢyᵢ²+j_{ry}yᵢ³ . . . (8)

Finally, the determination unit 6 calculates a statistics in each shot region by substituting the substrate coordinate positions of the center of each shot region into polynomials (3) to (8) whose coefficients have been calculated, and determines the calculated statistics as an alignment offset for an overlay correction value.

The above embodiment has exemplified the case in which resist pattern overlay is inspected by performing overlay inspection after the first developing step. However, the overlay of patterns formed on the substrate may be inspected by performing the overlay inspection step after the first etching step. The embodiment has also exemplified the case in which the line width of a formed pattern is inspected by performing line width inspection after the second etching step. However, the line width of a resist pattern on the substrate may be inspected by performing line width inspection after the second developing step.

As an example of calculating an alignment offset, this embodiment has exemplified the method of calculating a correction value based on a shift component, a magnification component, and a rotation component in each shot region. It is possible to use, as a simpler method, a method of calculating at least one of a shift component, a magnification component, and a rotation component, for example, using only a shift component, in each shot region as a correction value by using a different statistical process than that used in wafer alignment. As described above, the determination step is not limited to the above statistical process and the correction value calculated in the above manner.

As described above, this embodiment can be expected to improve the uniformity of the line widths of patterns by performing overlay optimization based on the line widths of the patterns formed in DP.

In addition, using a program that stores the contents of step S203 can cause the computer in the exposure system to execute processes such as calculating and determining an alignment offset based on the information generated by the exposure system, for example, the measured values of line widths.

In addition, devices can be manufactured by using the exposure system according to this embodiment. In this case, devices are manufactured through a step of forming a pattern on a substrate by using the above exposure system and other known steps. The devices can be semiconductor integrated circuit devices, liquid crystal display devices, and the like. The substrate can be a wafer, a glass plate, and the like. The known steps can be, for example, oxidation, film formation, deposition, doping, planarization, dicing, bonding, and packaging steps.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-275924, filed Oct. 27, 2008, which is hereby incorporated by reference herein in its entirety.

What is claimed is:

1. A method of forming a pattern on a first substrate by forming a first edge of the pattern on the first substrate through formation of a first resist pattern by coating the first substrate with a first resist, exposing the first resist, developing the first resist, forming a second edge of the pattern on the first substrate through formation of a second resist pattern by coating the substrate with a second resist, exposing the second resist, and developing the second resist, the method comprising:
measuring a line width of the pattern formed on the substrate; and
determining, based on the measured line width, a correction value which corrects information for positioning the substrate so as to reduce variations in the line width,
wherein a second edge is formed on a second substrate when positioning the second substrate in accordance with information corrected by using the determined correction value.

2. The method according to claim 1, wherein
the line width of the pattern is measured at a plurality of positions in each of the shot regions selected from a plurality of shot regions on the substrate, and
line width errors are calculated at the plurality of positions in each of the selected shot regions based on the measured line widths, at least one of a shift component, a magnification component, and a rotation component is statistically calculated in each of the selected shot regions based on the calculated line width errors, and at least one of a shift component, a magnification component, and a rotation component in each of the plurality of shot regions is calculated and determined as the correction value based on at least one of the calculated shift component, magnification component, and rotation component.

3. The method according to claim 1, wherein the pattern whose line width is measured includes a pattern for line width measurement different from a circuit pattern.

4. The method according to claim 1, wherein the pattern whose line width is measured includes a circuit pattern.

5. A system which forms a pattern on a substrate by forming a first edge of a pattern on a first substrate through formation of a first resist pattern by coating the first substrate with a first resist, exposing the first resist, developing the first resist, forming a second edge of the pattern on the first substrate through formation of a second resist pattern by coating the substrate with a second resist, exposing the second resist, and developing the second resist, the system comprising:
a coating apparatus configured to coat the substrate with a resist;
an exposure apparatus configured to expose a substrate;
a developing apparatus configured to develop a substrate;
an etching apparatus configured to etch a substrate;
a measurement device configured to measure a line width of the pattern formed on the first substrate;
a determination unit configured to determine, based on the measured line width, a correction value which corrects information for positioning the first substrate so as to reduce variations in the line width; and
a controller,
wherein the controller controls the measurement unit to measure the line width of the pattern formed on the substrate through the forming of the first and second edges, and
controls the exposure apparatus to form a second edge on a second substrate upon positioning of the second substrate in accordance with information corrected by using the determined correction value.

6. The system according to claim 5, wherein
the controller controls the measurement unit to measure the line width of the pattern at a plurality of positions in each of shot regions selected from a plurality of shot regions on the first substrate, and
the determination unit calculates line width errors at the plurality of positions based on the measured line widths, statistically calculates at least one of a shift component, a magnification component, and a rotation component in each of the selected shot regions based on the calculated line width errors, and calculates and determines, as the correction value, at least one of a shift component, a magnification component, and a rotation component in each of the plurality of shot regions based on at least one of the calculated shift component, magnification component, and rotation component.

7. A computer readable storage medium storing a program for causing a computer to process information generated by a system which comprises a coating apparatus configured to coat a substrate with a resist, an exposure apparatus configured to expose a substrate, a developing apparatus configured to develop a substrate, and an etching apparatus configured to etch a substrate, and forms a pattern on the first substrate by forming a first edge of a pattern on the first substrate through formation of a first resist pattern by coating the first substrate with a first resist, exposing the first resist, and developing the first resist, forming a second edge of the pattern on the first substrate through formation of a second resist pattern by coating the first substrate with a second resist, exposing the second resist, and developing the second resist, the program causing the computer to execute
determining a correction value which corrects information for positioning a second substrate on which a second edge is formed so as to reduce variations in line width, based on a measured value of a line width of the pattern formed on the first substrate.

8. The computer readable storage medium according to claim 7, wherein
a line width error is calculated based on line widths measured at a plurality of positions in each of shot regions selected from a plurality of shot regions on the first substrate, at least one of a shift component, a magnification component, and a rotation component is calculated in each of the selected shot regions based on the calculated line width errors, and at least one of a shift component, a magnification component, and a rotation component in each of the plurality of shot regions is calculated and determined as the correction value, based on at least one of the calculated shift component, magnification component, and rotation component.

9. A method of manufacturing a device, the method comprising forming a pattern on a first substrate by using an exposure system,
wherein the exposure system includes:
a coating apparatus configured to coat a substrate with a resist;
an exposure apparatus configured to expose a substrate;
a developing apparatus configured to develop a substrate;
an etching apparatus configured to etch a substrate;
a measurement device configured to measure a line width of a pattern formed on the first substrate;
a determination unit configured to determine, based on the measured line width, a correction value which corrects information for positioning the first substrate so as to reduce variations in line width; and
a controller,
and forms a pattern on the first substrate by forming a first edge of a pattern on the first substrate through formation of a first resist pattern by coating the first substrate with a first resist, exposing the first resist, and developing the first resist, and forming a second edge of the pattern on the first substrate through formation of a second resist pattern by coating the first substrate, on which the first edge is formed, with a second resist, exposing the second resist, and developing the second resist, and
the controller controls the measurement unit to measure the line width of the pattern formed on the first substrate through the forming of the first and second edges, and controls the exposure apparatus to form a second edge on a second substrate upon positioning of the second substrate in accordance with the information corrected by using the determined correction value.

10. A method of forming a first edge and a second edge of a pattern on a first substrate, the method comprising:
measuring a line width of the pattern; and
determining, based on the measured line width, a correction value which corrects information for positioning the first substrate in the forming of the second edge to reduce variations in the line width,
wherein the second edge is formed on a second substrate when positioning the first substrate in accordance with the corrected information.
